(19) United States
(12) Patent Application Publication
(10) Pub. No.: US 2024/0218152 A1
(43) Pub. Date: Jul. 4, 2024

(54) RESIN COMPOSITION AND ARTICLE MADE THEREFROM

(71) Applicant: Elite Material Co., Ltd., Taoyuan City (TW)

(72) Inventor: Chen-Yu HSIEH, Taoyuan City (TW)

(21) Appl. No.: 18/192,466

(22) Filed: Mar. 29, 2023

Related U.S. Application Data
(60) Provisional application No. 63/434,247, filed on Dec. 21, 2022.

(51) Int. Cl. C08K 5/01; C08F 212/08; C08F 212/36; C08J 5/24; C08L 23/16

(52) U.S. Cl. CPC C08K 5/01; C08F 212/08; C08F 212/36; C08J 5/24; C08L 23/16; C08J 2323/16; C08J 2325/08; C08L 2203/16; C08L 2203/20

(57) ABSTRACT

A resin composition includes a first compound and a second compound, wherein: the first compound has a structure of Formula (1); the second compound comprises bis(vinylphenyl) ethane, divinylbenzene-ethylstyrene-styrene copolymer, ethylene-propylene-ethylidenenorbornene copolymer or a combination thereof; and a weight ratio of the first compound and the second compound is between 1:5 and 5:1. The resin composition may be used to make a prepreg, a resin film, a laminate or a printed circuit board, and at least one of the following properties can be improved, including varnish shelf life, temperature coefficient of dielectric constant, dielectric constant and solder floating thermal resistance of multi-layer board.

### CROSS-REFERENCE TO RELATED APPLICATION

This application claims the priority benefits of U.S. provisional application No. 63/434,247, filed on Dec. 21, 2022. The entirety of the above-mentioned provisional patent application is hereby incorporated by reference herein and made a part of this specification.

### BACKGROUND

### 1. Field of the Disclosure

The present disclosure relates to a resin composition and more particularly to a resin composition useful for preparing a prepreg, a resin film, a laminate or a printed circuit board.

### 2. Description of Related Art

With the rapid development of electronic technology, the demands for electrical properties of products such as printed circuit boards have become increasingly challenging. When circuit boards are installed in an environment with significant temperature changes, such as in automotive electronic products or 5G base stations, the technical requirements include that the characteristics of the dielectric materials in the circuit boards are not easily affected by temperature changes. Therefore, there is a need for developing materials suitable for the aforesaid high performance circuit boards.

### SUMMARY

To overcome the problems facing prior arts, particularly the above-mentioned technical problems of conventional materials, it is a primary object of the present disclosure to provide a resin composition and an article made therefrom which may overcome the above-mentioned technical problems. Specifically, a primary object of the present disclosure is to provide a resin composition and an article made therefrom which may improve temperature coefficient of dielectric constant and dielectric constant and may at the same time improve at least one or more desirable properties including varnish shelf life and thermal resistance.

To achieve the above-mentioned objects, the present disclosure provides a resin composition comprising a first compound and a second compound, wherein:
the first compound has a structure of Formula (1):

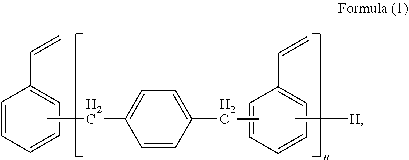

wherein n is 1 to 20;
the second compound comprises bis(vinylphenyl) ethane, divinylbenzene-ethylstyrene-styrene copolymer, ethylene-propylene-ethylidene norbornene copolymer or a combination thereof; and
a weight ratio of the first compound and the second compound is between 1:5 and 5:1.

For example, in one embodiment, the varnish made from the resin composition has a shelf life of greater than or equal to 30 days.

For example, in one embodiment, the resin composition further comprises inorganic filler, curing accelerator, flame retardant, polymerization inhibitor, solvent, silane coupling agent, coloring agent, toughening agent or a combination thereof.

To achieve the above-mentioned objects, the present disclosure further provides an article made from the resin composition, including a prepreg, a resin film, a laminate or a printed circuit board.

For example, in one embodiment, the articles made from the resin composition disclosed herein at least have one, more or all of the following properties:
a temperature coefficient of dielectric constant as measured and calculated by reference to JIS C2565 at 10 GHz of less than or equal to 43 ppm/° C.;
a dielectric constant as measured by reference to JIS C2565 at 10 GHz of less than or equal to 3.15; and
no delamination occurs after subjecting the article to a solder floating thermal resistance test of multi-layer board of 20 cycles by reference to IPC-TM-650 2.4.13.1.

### DESCRIPTION OF THE EMBODIMENTS

To enable those skilled in the art to further appreciate the features and effects of the present disclosure, words and terms contained in the specification and appended claims are described and defined. Unless otherwise defined, all technical and scientific terms used herein have the same meaning as commonly understood by those of ordinary skill in the art to which this disclosure pertains. In the case of conflict, the present document and definitions contained herein will control.

As used herein, the term “comprises,” “comprising,” “contains,” “containing,” “includes,” “including,” “encompass,” “encompassing,” “has,” “having” or any other variant thereof is construed as an open-ended transitional phrase intended to cover a non-exclusive inclusion. For example, a composition or article of manufacture that comprises a list of elements is not necessarily limited to only those elements but may include other elements not expressly listed or inherent to such composition or article of manufacture. Further, unless expressly stated to the contrary, the term “or” refers to an inclusive or and not to an exclusive or. For example, a condition “A or B” is satisfied by any one of the following: A is true (or present) and B is false (or not present), A is false (or not present) and B is true (or present), and both A and B are true (or present). In addition, whenever open-ended transitional phrases are used, such as “comprises,” “comprising,” “includes,” “including,” “encompass,” “encompassing,” “has,” “having” or any other variant thereof, it is understood that transitional phrases such as “consisting essentially of” and “consisting of” are also disclosed and included.

In this disclosure, features or conditions presented as a numerical range or a percentage range are merely for convenience and brevity. Therefore, a numerical range or a percentage range should be interpreted as encompassing and specifically disclosing all possible subranges and individual numerals or values therein, particularly all integers therein. For example, a range of “1 to 8” should be understood as explicitly disclosing all subranges such as 1 to 7, 2 to 8, 2 to 6, 3 to 6, 4 to 8, 3 to 8 and so on, particularly all subranges defined by integers, as well as disclosing all individual values such as 1, 2, 3, 4, 5, 6, 7 and 8. Similarly, a range of “between 1 and 8” should be understood as explicitly disclosing all ranges such as 1 to 8, 1 to 7, 2 to 8, 2 to 6, 3 to 6, 4 to 8, 3 to 8 and so on and encompassing the end points of the ranges. Unless otherwise defined, the aforesaid interpretation rule should be applied throughout the present disclosure regardless broadness of the scope.

Whenever amount, concentration or other numeral or parameter is expressed as a range, a preferred range or a series of upper and lower limits, it is understood that all ranges defined by any pair of the upper limit or preferred value and the lower limit or preferred value are specifically disclosed, regardless whether these ranges are explicitly described or not. In addition, unless otherwise defined, whenever a range is mentioned, the range should be interpreted as inclusive of the endpoints and every integers and fractions in the range.

Given the intended purposes and advantages of this disclosure are achieved, numerals or figures have the precision of their significant digits. For example, 40.0 should be understood as covering a range of 39.50 to 40.49.

As used herein, a Markush group or a list of items is used to describe examples or embodiments of the present disclosure. A skilled artisan will appreciate that all subgroups of members or items and individual members or items of the Markush group or list can also be used to describe the present disclosure. For example, when X is described as being “selected from a group consisting of X₁, X₂ and X₃,” it is intended to disclose the situations of X is X₁ and X is X₁ and/or X₂ and/or X₃. In addition, when a Markush group or a list of items is used to describe examples or embodiments of the present disclosure, a skilled artisan will understand that any subgroup or any combination of the members or items in the Markush group or list may also be used to describe the present disclosure. Therefore, for example, when X is described as being “selected from a group consisting of X₁, X₂ and X₃” and Y is described as being “selected from a group consisting of Y₁, Y₂ and Y₃,” the disclosure shall be interpreted as any combination of X is X₁ or X₂ or X₃ and Y is Y₁ or Y₂ or Y₃.

Unless otherwise specified, according to the present disclosure, a compound refers to a chemical substance formed by two or more elements bonded with chemical bonds and may comprise a small molecule compound and a polymer compound, but not limited thereto. Any compound disclosed herein is interpreted to not only include a single chemical substance but also include a class of chemical substances having the same kind of components or having the same property. In addition, as used herein, a mixture refers to a combination of two or more compounds.

Unless otherwise specified, the term “resin” is a widely used common name of a synthetic polymer and is construed in the present disclosure as comprising monomer and its combination, polymer and its combination or a combination of monomer and its polymer, but not limited thereto. For example, in the present disclosure, the term “maleimide resin” is construed to encompass a maleimide monomer, a maleimide polymer, a combination of maleimide monomers, a combination of maleimide polymers, or a combination of maleimide monomer(s) and maleimide polymer(s).

Unless otherwise specified, according to the present disclosure, a polymer refers to the product formed by monomer(s) via polymerization and usually comprises multiple aggregates of polymers respectively formed by multiple repeated simple structure units by covalent bonds; the monomer refers to the compound forming the polymer. A polymer may comprise a homopolymer, a copolymer, a prepolymer, an oligomer, etc., but not limited thereto. Unless otherwise specified, according to the present disclosure, the homopolymer refers to a polymer formed by polymerizing one kind of monomer. Unless otherwise specified, according to the present disclosure, the copolymer refers to a product formed by subjecting two or more kinds of monomers to a polymerization reaction. For example, copolymers may comprise: random copolymers, such as a structure of -AABABBBAAABBA-; alternating copolymers, such as a structure of -ABABABAB-; graft copolymers, such as a structure of -AA(A-BBBB)AA(A-BBBB)AAA-; and block copolymers, such as a structure of -AAAAA-BBBBBB-AAAAA-. The copolymer of the present disclosure may be modified, such as by maleic anhydride. Unless otherwise specified, according to the present disclosure, the prepolymer refers to a polymer having a lower molecular weight between the molecular weight of monomer and the molecular weight of final polymer, and the prepolymer contains a reactive functional group capable of participating further polymerization to obtain the final polymer product which has been fully crosslinked or cured. The term “polymer” includes but not limited to an oligomer, which is a polymer with 2-20, typically 2-5, repeating units.

Unless otherwise specified, according to the present disclosure, a modification comprises a product derived from a resin with its reactive functional group modified, a product derived from a crosslinking reaction of a resin and other resins, a product derived from homopolymerizing a resin, a product derived from copolymerizing a resin and other resins, etc. For example, such as but not limited thereto, a modification may refer to replacing a hydroxyl group with a vinyl group via a chemical reaction, or obtaining a terminal hydroxyl group from a chemical reaction of a terminal vinyl group and p-aminophenol.

Unless otherwise specified, as used herein, part(s) by weight represents weight part(s) in any weight unit, such as but not limited to kilogram, gram, pound and so on. For example, 100 parts by weight of the first compound may represent 100 kilograms of the first compound or 100 pounds of the first compound.

The following embodiments and examples are illustrative in nature and are not intended to limit the present disclosure and its application. In addition, the present disclosure is not bound by any theory described in the background and summary above or the following embodiments or examples.

As described above, a main object of the present disclosure is to provide a resin composition, comprising a first compound and a second compound, wherein:
the first compound has a structure of Formula (1):

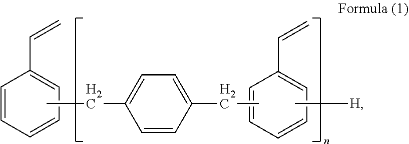

wherein n is 1 to 20;
the second compound comprises bis(vinylphenyl) ethane, divinylbenzene-ethylstyrene-styrene copolymer, ethylene-propylene-ethylidenenorbornene copolymer or a combination thereof; and
a weight ratio of the first compound and the second compound is between 1:5 and 5:1.

In Formula (1), n represents the repetition number of the structural unit in the parenthesis, and n is 1-20. For example, in one embodiment, n may be 1, 2, 3, 4, 5, 6, 7, 8, 9, 10, 11, 12, 13, 14, 15, 16, 17, 18, 19 or 20. Unless otherwise specified, the first compound may be available commercially or prepared by known methods. For example, the first compound may be prepared by the method described in Preparation Example 1 below, but not limited thereto. The reagents, amounts, and conditions used in Preparation Example 1 can be adjusted by those skilled in the art without undue experimentation to prepare the first compound.

In the present disclosure, the second compound comprises bis(vinylphenyl) ethane, divinylbenzene-ethylstyrene-styrene copolymer, ethylene-propylene-ethylidenenorbornene copolymer or a combination thereof. In particular, in the present disclosure, the second compound is a low polarity or non-polar compound. For example, the second compound has an absolute value of the difference in electronegativity of less than or equal to 0.4.

For example, in one embodiment, the bis(vinylphenyl) ethane may include various isomers, such as but not limited to 1,2-bis(4-vinylphenyl) ethane, 1,2-(3-vinylphenyl-4-vinylphenyl) ethane, 1,2-(2-vinylphenyl-4-vinylphenyl) ethane, 1,2-bis(3-vinylphenyl) ethane, 1,2-(3-vinylphenyl-2-vinylphenyl) ethane, 1,2-bis(2-vinylphenyl) ethane or a combination thereof. More preferred is 1,2-bis(4-vinylphenyl) ethane, 1,2-(3-vinylphenyl-4-vinylphenyl) ethane, 1,2-bis(3-vinylphenyl) ethane or a combination thereof.

For example, in one embodiment, the divinylbenzene-ethylstyrene-styrene copolymer refers to a terpolymer obtained by polymerizing divinylbenzene, ethylstyrene and styrene, wherein the divinylbenzene may include various isomers, such as but not limited to 1,2-divinylbenzene, 1,3-divinylbenzene, 1,4-divinylbenzene or a combination thereof, and the ethylstyrene may also include various isomers, such as but not limited to 2-ethylstyrene, 3-ethylstyrene, 4-ethylstyrene, or a combination thereof. Unless otherwise specified, the divinylbenzene-ethylstyrene-styrene copolymer may be available commercially or prepared by known methods. For example, the divinylbenzene-ethylstyrene-styrene copolymer may be prepared by the method described in Preparation Example 2 below, but not limited thereto. The reagents, amounts, and conditions used in Preparation Example 2 can be adjusted by those skilled in the art without undue experimentation to prepare divinylbenzene-ethylstyrene-styrene copolymer.

For example, in one embodiment, the ethylene-propylene-ethylidenenorbornene copolymer refers to a terpolymer obtained by polymerizing ethylene, propylene and ethylidenenorbornene, wherein the ethylidenenorbornene may include various isomers, and the content of each monomer in the ethylene-propylene-ethylidenenorbornene copolymer is not particularly limited (e.g., ethylene content=70-75 wt %, propylene content=20.5-26.5 wt %, and ethylidenenorbornene content=3.5-4.5 wt %, but not limited thereto). Unless otherwise specified, the ethylene-propylene-ethylidenenorbornene copolymer may be available commercially (e.g., EPT™ X-3012P, available from Mitsui Chemicals, or trilene 67 and trilene 77, available from Lion Elastomers, but not limited thereto) or prepared by known methods.

In the present disclosure, the resin composition has a weight ratio of the first compound and the second compound of between 1:5 and 5:1, such as but not limited to 1:5, 1:4, 1:3, 1:2, 1:1, 2:1, 3:1, 4:1 or 5:1. For example, if the amount of the first compound in the resin composition is 100 parts by weight, the amount of the second compound may be 20 to 500 parts by weight. For example, in one embodiment, the resin composition of the present disclosure comprises 100 parts by weight of the first compound and 20, 50, 60, 65, 100 or 500 parts by weight of the second compound.

In addition to the first compound and the second compound, the resin composition may also further optionally comprise inorganic filler, curing accelerator, flame retardant, polymerization inhibitor, solvent, silane coupling agent, coloring agent, toughening agent or a combination thereof, but not limited thereto.

For example, the inorganic filler may be any one or more inorganic fillers used for preparing a prepreg, a resin film, a laminate or a printed circuit board; examples of the inorganic filler include but are not limited to silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, zinc oxide, zirconium oxide, mica, boehmite (AlOOH), calcined talc, talc, silicon nitride and calcined kaolin. Moreover, the inorganic filler can be spherical, fibrous, plate-like, particulate, flake-like or whisker-like in shape and can be optionally pretreated by a silane coupling agent. Unless otherwise specified, the amount of the inorganic filler described above is not particularly limited and may range from 30 parts by weight to 300 parts by weight of the inorganic filler relative to 100 parts by weight of the first compound, for example.

For example, the curing accelerator (including curing initiator) may comprise a catalyst, such as a Lewis base or a Lewis acid. The Lewis base may comprise any one or more of imidazole, boron trifluoride-amine complex, ethyltriphenyl phosphonium chloride, 2-methylimidazole (2MI), 2-phenyl-1H-imidazole (2PZ), 2-ethyl-4-methylimidazole (2E4MI), triphenylphosphine (TPP) and 4-dimethylaminopyridine (DMAP). The Lewis acid may comprise metal salt compounds, such as those of manganese, iron, cobalt, nickel, copper and zinc, such as zinc octanoate or cobalt octanoate. The curing accelerator also includes a curing initiator, such as a peroxide capable of producing free radicals, examples of curing initiator including but not limited to dicumyl peroxide, tert-butyl peroxybenzoate, dibenzoyl peroxide (BPO), 2,5-dimethyl-2,5-di(tert-butylperoxy)-3-hexyne (25B), bis(tert-butylperoxyisopropyl)benzene or a combination thereof. Unless otherwise specified, the amount of the curing accelerator described above is not particularly limited and may range from 0.1 part by weight to 2 parts by weight of the curing accelerator relative to 100 parts by weight of the first compound, for example.

For example, the flame retardant used herein may be any one or more flame retardants useful for preparing a prepreg, a resin film, a laminate or a printed circuit board, examples including but not limited to a phosphorus-containing flame retardant, preferably comprising ammonium polyphosphate, hydroquinone bis-(diphenyl phosphate), bisphenol A bis-(diphenylphosphate), tri(2-carboxyethyl) phosphine (TCEP), phosphoric acid tris(chloroisopropyl) ester, trimethyl phosphate (TMP), dimethyl methyl phosphonate (DMMP), resorcinol bis(dixylenyl phosphate) (RDXP, such as commercially available PX-200, PX-201, and PX-202), phosphazene (such as commercially available SPB-100, SPH-100, and SPV-100), melamine polyphosphate, DOPO (9,10-dihydro-9-oxa-10-phosphaphenanthrene-10-oxide) and its derivatives or resins, DPPO (diphenylphosphine oxide) and its derivatives or resins, melamine cyanurate, tri-hydroxy ethyl isocyanurate, aluminium phosphinate (e.g., commercially available OP-930 and OP-935), or a combination thereof.

For example, the flame retardant may be a DPPO compound (e.g., di-DPPO compound, such as commercially available PQ-60), a DOPO compound (e.g., di-DOPO compound), a DOPO resin (e.g., DOPO-HQ, DOPO-NQ, DOPO-PN, and DOPO-BPN) and a DOPO-containing epoxy resin, wherein DOPO-PN is a DOPO phenol novolac compound, and DOPO-BPN may be a DOPO-containing bisphenol novolac compound, such as DOPO-BPAN (DOPO-bisphenol A novolac), DOPO-BPFN (DOPO-bisphenol F novolac) or DOPO-BPSN (DOPO-bisphenol S novolac). Unless otherwise specified, the amount of the aforesaid flame retardant is not particularly limited.

For example, the polymerization inhibitor may comprise, but not limited to, 1,1-diphenyl-2-picrylhydrazyl radical, methyl acrylonitrile, 2,2,6,6-tetramethyl-1-oxo-piperidine, dithioester, nitroxide-mediated radical, triphenylmethyl radical, metal ion radical, sulfur radical, hydroquinone, 4-methoxyphenol, p-benzoquinone, phenothiazine, 0-phenylnaphthylamine, 4-t-butylcatechol, methylene blue, 4,4′-butylidenebis(6-t-butyl-3-methylphenol), 2,2′-methylenebis(4-ethyl-6-t-butylphenol) or a combination thereof. For example, the nitroxide-mediated radical may comprise, but not limited to, nitroxide radicals derived from cyclic hydroxylamines, such as 2,2,6,6-substituted piperidine 1-oxyl free radical, 2,2,5,5-substituted pyrrolidine 1-oxyl free radical or the like. Preferred substitutes include alkyl groups with 4 or fewer carbon atoms, such as methyl group or ethyl group. Examples of the compound containing a nitroxide radical include but are not limited to 2,2,6,6-tetramethylpiperidine 1-oxyl free radical, 2,2,6,6-tetraethylpiperidine 1-oxyl free radical, 2,2,6,6-tetramethyl-4-oxo-piperidine 1-oxyl free radical, 2,2,5,5-tetramethylpyrrolidine 1-oxyl free radical, 1,1,3,3-tetramethyl-2-isoindoline oxygen radical, N,N-di-tert-butylamine oxygen free radical and so on. Nitroxide radicals may also be replaced by using stable radicals such as galvinoxyl radicals. The polymerization inhibitor suitable for the resin composition of the present disclosure may include products derived from the polymerization inhibitor with its hydrogen atom or group substituted by other atom or group. Examples include products derived from a polymerization inhibitor with its hydrogen atom substituted by an amino group, a hydroxyl group, a carbonyl group or the like.

For example, the solvent is not particularly limited and may be any solvent suitable for dissolving the resin composition disclosed herein, example including, but not limited to, methanol, ethanol, ethylene glycol monomethyl ether, acetone, butanone (methyl ethyl ketone), methyl isobutyl ketone, cyclohexanone, toluene, xylene, methoxyethyl acetate, ethoxyethyl acetate, propoxyethyl acetate, ethyl acetate, dimethylformamide, dimethylacetamide, propylene glycol methyl ether, or a mixture thereof. The amount of solvent is not particularly limited and may be adjusted according to the viscosity required for the resin composition.

For example, the silane coupling agent may comprise silane (such as but not limited to siloxane) and may be further categorized according to the functional groups into amino silane, epoxide silane, vinyl silane, acrylate silane, methacrylate silane, hydroxyl silane, isocyanate silane, methacryloxy silane and acryloxy silane. The amount of silane coupling agent is not particularly limited and may be adjusted according to the dispersivity of inorganic filler used in the resin composition.

For example, the coloring agent may comprise but not limited to dye or pigment.

As used herein, the purpose of adding toughening agent is to improve the toughness of the resin composition. For example, the toughening agent may comprise, but not limited to, carboxyl-terminated butadiene acrylonitrile rubber (CTBN rubber), core-shell rubber, or a combination thereof.

The resin composition of various embodiments may be processed to make different articles, such as those suitable for use as components in electronic products, including but not limited to a prepreg, a resin film, a laminate or a printed circuit board.

For example, the resin compositions of various embodiments may be used to make prepregs.

For example, the prepreg disclosed herein has a reinforcement material and a layered structure formed thereon, wherein the layered structure is made by heating the resin composition at high temperature to a semi-cured state (B-stage). Suitable baking temperature for making the prepreg may be for example 100° C. to 140° C. The reinforcement material may be a fiber material or a non-fiber material, configured as any one of woven fabric and non-woven fabric, and the woven fabric preferably comprises fiberglass fabrics. Types of fiberglass fabrics are not particularly limited and may be any commercial fiberglass fabric useful for various printed circuit boards, such as E-glass fiber fabric, D-glass fiber fabric, S-glass fiber fabric, T-glass fiber fabric, L-glass fiber fabric or Q-glass fiber fabric, wherein the fiber may comprise yarns and rovings, in spread form or standard form. Non-woven fabric preferably comprises liquid crystal polymer non-woven fabric, such as polyester non-woven fabric, polyurethane non-woven fabric and so on, but not limited thereto. Woven fabric may also comprise liquid crystal polymer woven fabric, such as polyester woven fabric, polyurethane woven fabric and so on, but not limited thereto. The reinforcement material may increase the mechanical strength of the prepreg. In one preferred embodiment, the reinforcement material can be optionally pre-treated by a silane coupling agent. The prepreg may be further heated and cured to the C-stage to form an insulation layer.

For example, by well mixing the resin composition to form a varnish, loading the varnish into an impregnation tank, impregnating a fiberglass fabric into the impregnation tank to adhere the resin composition onto the fiberglass fabric, and finally heating and baking the resin composition at a proper temperature to a semi-cured state, a prepreg may be obtained.

For example, the article made from the resin composition disclosed herein may be a resin film.

For example, in one embodiment, the resin film disclosed herein is prepared by heating and baking the resin composition to the semi-cured state (B-stage). For example, the resin composition may be selectively coated on a liquid crystal polymer film, a polyethylene terephthalate film (PET film) or a polyimide film; for example, the resin composition from each embodiment may be coated on a copper foil to uniformly adhere the resin composition thereon, followed by heating and baking at 60° C. to 120° C. for 3 to 10 minutes to a semi-cured state to form a resin film, so as to obtain a copper-clad resin film (i.e., resin coated copper).

For example, the resin compositions of various embodiments may be used to make laminates.

For example, in one embodiment, the laminate of the disclosure comprises at least two metal foils and an insulation layer disposed between the metal foils, wherein the insulation layer is made by curing the resin composition at high temperature and high pressure to the C-stage, a suitable curing temperature being for example between 180° C. and 240° C. and preferably between 200° C. and 220° C. and a suitable curing time being 60 to 150 minutes and preferably 90 to 120 minutes. The insulation layer may be formed by curing the aforesaid prepreg or resin film to the C-stage. The metal foil may comprise copper, aluminum, nickel, platinum, silver, gold or alloy thereof, such as a copper foil. In one embodiment, the laminate is a copper-clad laminate (CCL).

In addition, the laminate may be further processed by trace formation processes to make a circuit board, such as a printed circuit board.

In one embodiment of making a printed circuit board, a double-sided copper-clad laminate (such as product EM-891, available from Elite Material Co., Ltd.) with a thickness of 28 mil and having 0.5 ounce (oz) HVLP (hyper very low profile) copper foils may be used, which is subject to drilling and then electroplating, so as to form electrical conduction between the top layer copper foil and the bottom layer copper foil. Then the top layer copper foil and the bottom layer copper foil are etched to form inner layer circuits. Then brown oxidation and roughening are performed on the inner layer circuits to form uneven structures on the surface to increase roughness. Next, a vacuum lamination apparatus is used to laminate the assembly of a copper foil, the prepreg, the inner layer circuit, the prepreg and a copper foil stacked in said order by heating at 190° C. to 220° C. for 90 to 200 minutes to cure the insulation material of the prepregs. Next, black oxidation, drilling, copper plating and other known circuit board processes are performed on the outmost copper foils so as to obtain the printed circuit board.

In one embodiment, the resin composition of the present disclosure or the article made therefrom may achieve improvement in one or more of the following properties: varnish shelf life, temperature coefficient of dielectric constant, dielectric constant and solder floating thermal resistance of multi-layer board.

For example, in one embodiment, the resin composition disclosed herein or the article made therefrom has one, more or all of the following properties:
a varnish made from the resin composition has a shelf life of greater than or equal to 30 days, such as greater than or equal to 30 days, 35 days, 40 days, 45 days, 50 days, 55 days, 60 days, 90 days or 120 days, such as a shelf life of between 30 days and 120 days;
a temperature coefficient of dielectric constant as measured and calculated by reference to JIS C2565 at 10 GHz of less than or equal to 43 ppm/° C., such as between 34 ppm/° C. and 43 ppm/° C.;
a dielectric constant as measured by reference to JIS C2565 at 10 GHz of less than or equal to 3.15, such as between 2.93 and 3.15; and no delamination occurs after subjecting the article to a solder floating thermal resistance test of multi-layer board of 20 cycles by reference to IPC-TM-650 2.4.13.1.

Raw materials below were used to prepare the resin compositions of various Examples and Comparative Examples of the present disclosure according to the amount listed in Table 1 to Table 4 and further fabricated to prepare test samples.

Chemical reagents used in Examples and Comparative Examples of resin composition disclosed herein and chemical reagents used in Preparation Examples are listed below:
First compound: made by Preparation Example 1.
BVPE: 1,2-bis(vinylphenyl) ethane, available from Linchuan Chemical Co., Ltd., having an absolute value of the difference in electronegativity of less than or equal to 0.4.
Copolymer 1: divinylbenzene-ethylstyrene-styrene copolymer, made by Preparation Example 2, having an absolute value of the difference in electronegativity of less than or equal to 0.4.
Copolymer 2: ethylene/propylene/5-ethylidene-2-norbornene copolymer, under the product name EPT™ X-3012P, available from Mitsui Chemicals, wherein the Mooney viscosity ML1+4(100° C.)=15, ethylene content=72 wt %, propylene content=24.4 wt %, 5-ethylidene-2-norbornene content=3.6 wt %, having an absolute value of the difference in electronegativity of less than or equal to 0.4.
SA9000: methacrylate group-containing polyphenylene ether resin, available from Sabic.
Ricon100: styrene-butadiene copolymer, available from Cray Valley.
BMI-70: 3,3′-dimethyl-5,5′-diethyl-4,4′-diphenylmethane bismaleimide, available from K.I Chemical Industry Co., Ltd.
DCPD: dicyclopentadiene, available from Sigma-Aldrich. 25B: 2,5-dimethyl-2,5-di(tert-butylperoxy)-3-hexyne, available from NOF Corporation.
SC2050 SMJ: chemically synthesized silica, surface treated by methacrylate siloxane, available from Admatechs.
Toluene: commercially available.
MEK: methyl ethyl ketone, commercially available.

### Preparation Example 1

296 parts by weight of 2-bromoethylbenzene (manufactured by Tokyo Chemical Industry Co., Ltd.), 70 parts by weight of α,α′-dichloro-p-xylene (manufactured by Tokyo Chemical Industry Co., Ltd.) and 18.4 parts by weight of methanesulfonic acid (manufactured by Tokyo Chemical Industry Co., Ltd.) were reacted at 130° C. for 8 hours, followed by cooled to room temperature, neutralized with aqueous sodium hydroxide solution, and extracted with 1200 parts by weight of toluene. The organic layer was washed with water. The solvent and excess 2-bromoethylbenzene were removed by distillation under heating and reduced pressure to obtain the intermediate. The molar ratio of 2-bromoethylbenzene to α,α′-dichloro-p-xylene may be 4:1; methanesulfonic acid was used as an acidic catalyst and may be replaced by other acidic catalysts such as hydrochloric acid and phosphoric acid; and the reaction conditions may be 40 to 180° C. for 0.5 to 20 hours.

22 parts by weight of the aforesaid intermediate, 50 parts by weight of toluene (other aromatic solvents may also be used, such as xylene), 150 parts by weight of dimethyl sulfoxide (other aprotic polar solvents may also be used, such as dimethyl sulfone), 15 parts by weight of water and 5.4 parts by weight of sodium hydroxide (other alkaline catalysts may also be used, such as potassium hydroxide and potassium carbonate) were reacted at 40° C. for 5 hours, followed by cooled to room temperature, and then added with 100 parts by weight of toluene. The organic layer was washed with water, and the solvent was removed by distillation under heating and reduced pressure to obtain the first compound of Formula (1).

### Preparation Example 2

100 parts by weight of toluene solvent, 60 parts by weight of 1,4-divinylbenzene (available from Merck), 30 parts by weight of styrene and 40 parts by weight of 4-ethylstyrene (available from Alfa Chemistry) were added in a three-necked flask and stirred to dissolve completely, followed by adding 2 parts by weight of tetrabutylammonium and 1 part by weight of stannic chloride. The reaction was performed under stirring at 100° C. for 3 hours. After the reaction was completed, steps including filtration, purification, methanol precipitation and cooling were performed to obtain a solid Copolymer 1, which was a divinylbenzene-ethylstyrene-styrene copolymer, with Mn of 2000-3000 g/mol and an vinyl equivalence of 150-350 g/eq.

Compositions and test results of resin compositions of Examples and Comparative Examples are listed below (in part by weight):

TABLE 1
Resin compositions of Examples (in part by weight) and test results

| Component | Name | E1 | E2 | E3 | E4 | E5 | E6 |
|---|---|---|---|---|---|---|---|
| first compound | | 100 | 100 | 100 | 100 | 100 | 100 |
| second compound | BVPE | 20 | 50 | 100 | 500 | | |
| | Copolymer 1 | | | | | 50 | 20 |
| | Copolymer 2 | | | | | | |
| other compound | SA9000 | | | | | | |
| | Ricon100 | | | | | | |
| | BMI-70 | | | | | | |
| | DCPD | | | | | | |
| curing accelerator | 25B | 1 | 1 | 1 | 1 | 1 | 1 |
| inorganic filler | SC2050 SMJ | 100 | 100 | 100 | 100 | 100 | 100 |
| solvent | toluene | 100 | 350 | 500 | 2500 | 120 | 100 |
| | MEK | | | | | | 20 |
| Property | Unit | E1 | E2 | E3 | E4 | E5 | E6 |
| varnish shelf life | none | N | N | N | N | N | N |
| temperature coefficient of | ppm/° C. | 43 | 42 | 42 | 41 | 38 | 43 |
| dielectric constant | | | | | | | |
| dielectric constant | none | 3.15 | 3.11 | 3.10 | 3.08 | 3.01 | 3.10 |
| solder floating thermal | none | pass | pass | pass | pass | pass | pass |
| resistance of multi-layer board | | | | | | | |

TABLE 2
Resin compositions of Examples (in part by weight) and test results

| Component | Name | E7 | E8 | E9 | E10 | E11 |
|---|---|---|---|---|---|---|
| first compound | | 100 | 100 | 100 | 100 | 100 |
| second compound | BVPE | | | 25 | 30 | |
| | Copolymer 1 | 500 | | 20 | | 40 |
| | Copolymer 2 | | 50 | 20 | 35 | 20 |
| other compound | SA9000 | | | | | |
| | Ricon100 | | | | | |
| | BMI-70 | | | | | |
| | DCPD | | | | | |
| curing accelerator | 25B | 1 | 1 | 1 | 0.1 | 2 |
| inorganic filler | SC2050 SMJ | 300 | 100 | 100 | 30 | 130 |
| solvent | toluene | 100 | 120 | 120 | 200 | 600 |
| | MEK | 50 | | | 20 | 150 |
| Property | Unit | E7 | E8 | E9 | E10 | E11 |
| varnish shelf life | none | N | N | N | N | N |
| temperature coefficient of | ppm/° C. | 40 | 39 | 38 | 35 | 34 |
| dielectric constant | | | | | | |
| dielectric constant | none | 3.05 | 3.03 | 2.99 | 2.94 | 2.93 |
| solder floating thermal | none | pass | pass | pass | pass | pass |
| resistance of multi-layer board | | | | | | |

TABLE 3
Resin compositions of Comparative Examples (in part by weight) and test results

| Component | Name | C1 | C2 | C3 | C4 | C5 | C6 |
|---|---|---|---|---|---|---|---|
| first compound | | 100 | 100 | 100 | 100 | | |
| second compound | BVPE | | | | | 50 | 50 |
| | Copolymer 1 | | | | | | |
| | Copolymer 2 | | | | | | |
| other compound | SA9000 | 50 | | | | 100 | |
| | Ricon100 | | 50 | | | | 100 |
| | BMI-70 | | | 50 | | | |
| | DCPD | | | | 50 | | |
| curing accelerator | 25B | 1 | 1 | 1 | 1 | 1 | 1 |
| inorganic filler | SC2050 SMJ | 100 | 100 | 100 | 100 | 100 | 100 |
| solvent | toluene | 120 | 120 | 120 | 120 | 350 | 350 |
| | MEK | | | | | | |
| Property | Unit | C1 | C2 | C3 | C4 | C5 | C6 |
| varnish shelf life | none | N | N | N | N | Y | Y |
| temperature coefficient of | ppm/° C. | 77 | 65 | 80 | 51 | 73 | 67 |
| dielectric constant | | | | | | | |
| dielectric constant | none | 3.61 | 3.42 | 3.82 | 3.31 | 3.71 | 3.43 |
| solder floating thermal | none | pass | pass | pass | NG | NG | NG |
| resistance of multi-layer board | | | | | | | |

TABLE 4
Resin compositions of Comparative Examples (in part by weight) and test results

| Component | Name | C7 | C8 | C9 | C10 | C11 | C12 |
|---|---|---|---|---|---|---|---|
| first compound | | | | | | 150 | |
| second compound | BVPE | 50 | 50 | | | | 150 |
| | Copolymer 1 | | | 50 | | | |
| | Copolymer 2 | | | | 50 | | |
| other compound | SA9000 | | | 100 | 100 | | |
| | Ricon100 | | | | | | |
| | BMI-70 | 100 | | | | | |
| | DCPD | | 100 | | | | |
| curing accelerator | 25B | 1 | 1 | 1 | 1 | 1 | 1 |
| inorganic filler | SC2050 SMJ | 100 | 100 | 100 | 100 | 100 | 100 |
| solvent | toluene | 350 | 350 | 120 | 120 | 350 | 750 |
| | MEK | | | | | | |
| Property | Unit | C7 | C8 | C9 | C10 | C11 | C12 |
| varnish shelf life | none | Y | Y | N | N | N | Y |
| temperature coefficient of | ppm/° C. | 90 | 61 | 85 | 80 | 60 | can not |
| dielectric constant | | | | | | | be |
| dielectric constant | none | 3.80 | 3.35 | 3.43 | 3.29 | 3.00 | formed |
| solder floating thermal | none | NG | NG | pass | pass | NG | |
| resistance of multi-layer board | | | | | | | |

Samples (specimens) for the properties measured above were prepared as described below and tested and analyzed under specified conditions below.

### 1. Prepreg (PP)

Resin composition (in part by weight) from each Example or each Comparative Example was separately added to a stirred tank and well-mixed to form a varnish. Then the varnish was loaded to an impregnation tank, and a fiberglass fabric (e.g., 1078 E-glass fiber fabric, available from Asahi) was impregnated into the impregnation tank to adhere the resin composition onto the fiberglass fabric, followed by heating at 100° C. to 140° C. to the semi-cured state (B-stage) to obtain a prepreg, having a resin content of about 70%.

### 2. Copper-Containing Laminate 1 (Obtained by Laminating Two Prepregs)

Two 1 oz hyper very low profile 3 (HVLP3) copper foils and two prepregs obtained from 1078 E-glass fiber fabrics impregnated with each Example or Comparative Example were prepared, each prepreg having a resin content of about 70%. A copper foil, two prepregs and a copper foil were superimposed in such order and then subjected to a vacuum condition for lamination at 250 psi to 600 psi and 200° C. to 220° C. for 90 minutes to 120 minutes to form each copper-containing laminate 1.

Insulation layers were formed by laminating two sheets of prepreg between the two copper foils, and the resin content of the insulation layers is about 70%.

### 3. Copper-Containing Laminate 2 (Obtained by Laminating Eight Prepregs)

Two 1 oz hyper very low profile 3 (HVLP3) copper foils and eight prepregs obtained from 1078 E-glass fiber fabrics impregnated with each Example or Comparative Example were prepared, each prepreg having a resin content of about 70%. A copper foil, eight prepregs and a copper foil were superimposed in such order and then subjected to a vacuum condition for lamination at 250 psi to 600 psi and 200° C. to 220° C. for 90 minutes to 120 minutes to form each copper-containing laminate 2. Insulation layers were formed by laminating eight sheets of prepreg between the two copper foils, and the resin content of the insulation layers is about 70%.

### 4. Copper-Free Laminate 1 (Obtained by Laminating Two Prepregs)

Each aforesaid copper-containing laminate 1 was etched to remove the two copper foils to obtain the copper-free laminate 1 (obtained by laminating two prepregs), having a resin content of about 70%.

For each sample, test items and test methods are described below.

### Varnish Shelf Life

A varnish was prepared from the resin composition of each Example or Comparative Example without adding silica; the varnish was well mixed and fully dissolved and stood still at 25° C. for one month (30 days) and observed by naked eyes on the 30th day to determine whether or not the varnish precipitates to form brown solid substance. A designation of “N” represents no precipitation occurred, indicating a varnish shelf life of greater than or equal to one month, such as a varnish shelf life of one to one-and-a-half months, such as a varnish shelf life of one month to one month and a week. The presence of at least one precipitate of 0.5-5 mm in length, usually in brown color, is designated as “Y”, representing a varnish shelf life of less than one month. Precipitation of the varnish will cause variation and deterioration in properties of laminates made therefrom.

### Temperature Coefficient of Dielectric Constant (TCDk)

Each copper-free laminate 1 sample (obtained by laminating two prepregs, resin content of about 70%) was subjected to the measurement of dielectric constant at −50° C. (defined as Dk 1) and dielectric constant at 150° C. (defined as Dk 2) respectively by reference to JIS C2565 at a working frequency of 10 GHz. The calculation method for the temperature coefficient of dielectric constant is |(Dk 2−Dk 1)/(150−(−50))|, in ppm/° C. Generally, a difference in TCDk of greater than or equal to 5 ppm/° C. represents a substantial difference (i.e., significant technical difficulty) in different samples.

### Dielectric Constant (Dk)

The aforesaid copper-free laminate 1 sample (obtained by laminating two prepregs, resin content of about 70%) was subjected to the measurement. Each sample was measured by using a microwave dielectrometer (available from AET Corp.) by reference to JIS C2565 at room temperature (about 25° C.) and under 10 GHz frequency. Under a 10 GHz frequency, for a low Dk material, a difference in Dk of greater than or equal to 0.3 represents a significant difference (i.e., significant technical difficulty) in dielectric constant in different laminates.

### Solder Floating Thermal Resistance (Solder Dipping, S/D)

The aforesaid copper-containing laminate 2 (obtained by laminating eight prepregs, resin content of about 70%) was subjected to the measurement. The specimen was cut to a length of 20 cm and a width of 10 cm and, by reference to IPC-TM-650 2.4.13.1, horizontally placed and floated on the solder bath of a 288° C. solder pot; each process of 10 seconds of floating on the solder bath and then removing the specimen therefrom for 30 seconds of cooling represents one cycle, followed by subjecting the same specimen to another 10 seconds of floating on the solder bath and 30 seconds of cooling as the second cycle, and so on. The processes were repeated for a total of 20 cycles during the test. After 20 cycles, the specimen was sliced and then inspected with an optical microscope to determine the presence or absence of delamination. Three specimens were tested for each Example or Comparative Example. In the test results, if delamination was observed in at least one of the three samples, a designation of “NG” was given; otherwise, if no delamination was observed in all three samples, a designation of “pass” was given. Generally, interlayer separation between insulation layers of a specimen is considered as delamination, and interlayer separation may cause blistering and delamination between any layers of the laminate.

The following observations can be made according to the test results above.

If the resin composition, such as Comparative Examples C1-C4, does not contain bis(vinylphenyl) ethane, divinylbenzene-ethylstyrene-styrene copolymer or ethylene-propylene-ethylidenenorbornene copolymer, but contains other compounds with higher polarity (having an absolute value of the difference in electronegativity of greater than 0.4), the article made therefrom will fail to achieve desirable improvement in at least one of the properties including temperature coefficient of dielectric constant, dielectric constant and solder floating thermal resistance of multi-layer board.

If the resin composition, such as Comparative Examples C5-C10, does not contain the first compound disclosed herein, but uses other compounds in conjunction with the second compound disclosed herein, the article made therefrom will fail to achieve desirable improvement in at least one of the properties including varnish shelf life, temperature coefficient of dielectric constant, dielectric constant and solder floating thermal resistance of multi-layer board.

If the resin composition, such as Comparative Example C11, contains only the first compound, but not contains the second compound such as bis(vinylphenyl) ethane, divinylbenzene-ethylstyrene-styrene copolymer or ethylene-propylene-ethylidenenorbornene copolymer, the article made therefrom will fail to achieve desirable improvement in at least one of the properties including temperature coefficient of dielectric constant and solder floating thermal resistance of multi-layer board.

If the resin composition, such as Comparative Example C12, contains only the second compound, but not contains the first compound disclosed herein, it will not only cause a poor varnish shelf life but also fail to be formed into an article.

In contrast, the resin composition of the present disclosure, such as Examples E1-E11, can achieve at the same time desirable properties including a varnish shelf life of greater than or equal to 30 days, a temperature coefficient of dielectric constant of less than or equal to 43 ppm/° C., a dielectric constant of less than or equal to 3.15 and no delamination occurring after subjecting the article to a solder floating thermal resistance test of multi-layer board of 20 cycles.

The above detailed description is merely illustrative in nature and is not intended to limit the embodiments of the subject matter or the application and use of such embodiments. As used herein, the term “exemplary” means “serving as an example, instance, or illustration.” Any implementation described herein as exemplary is not necessarily to be construed as preferred or advantageous over other implementations.

Moreover, while at least one exemplary example or comparative example has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments. Also, various changes can be made in the function and arrangement of elements without departing from the scope defined by the claims, which include known equivalents and foreseeable equivalents at the time of filing this patent application.

What is claimed is:

1. A resin composition comprising a first compound and a second compound, wherein:
the first compound has a structure of Formula (1): 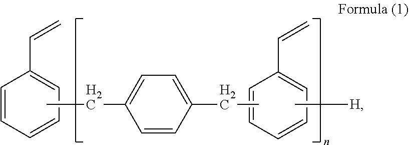
wherein n is 1 to 20;
the second compound comprises bis(vinylphenyl) ethane, divinylbenzene-ethylstyrene-styrene copolymer, ethylene-propylene-ethylidenenorbornene copolymer or a combination thereof; and
a weight ratio of the first compound and the second compound is between 1:5 and 5:1.

2. The resin composition of claim 1, wherein a varnish made from the resin composition has a shelf life of greater than or equal to 30 days.

3. The resin composition of claim 1, further comprising inorganic filler, curing accelerator, flame retardant, polymerization inhibitor, solvent, silane coupling agent, coloring agent, toughening agent or a combination thereof.

4. An article made from the resin composition of claim 1, comprising a prepreg, a resin film, a laminate or a printed circuit board.

5. The article of claim 4, having a temperature coefficient of dielectric constant as measured and calculated by reference to JIS C2565 at 10 GHz of less than or equal to 43 ppm/° C.

6. The article of claim 4, having a dielectric constant as measured by reference to JIS C2565 at 10 GHz of less than or equal to 3.15.

7. The article of claim 4, wherein no delamination occurs after subjecting the article to a solder floating thermal resistance test of multi-layer board of 20 cycles by reference to IPC-TM-650 2.4.13.1.
